(19) United States
(12) Patent Application Publication
(10) Pub. No.: US 2012/0223749 A1
(43) Pub. Date: Sep. 6, 2012

(54) CLOCK SYNCHRONIZATION CIRCUIT AND SEMICONDUCTOR INTEGRATED CIRCUIT

(75) Inventor: Tsuneki SASAKI, Kanagawa (JP)

(73) Assignee: RENESAS ELECTRONICS CORPORATION, Kanagawa (JP)

(21) Appl. No.: 13/404,397

(22) Filed: Feb. 24, 2012

(30) Foreign Application Priority Data
Mar. 2, 2011 (JP) 2011-044819

(51) Int. Cl. H03L 7/00

(52) U.S. Cl. 327/141

(57) ABSTRACT

A clock synchronization circuit receives a base clock, a first synchronization signal for synchronizing the base clock and a system clock, and a selection signal containing information about the division ratio of the system clock, holds the first synchronization signal over a predetermined time on the basis of the selection signal, and outputs, in synchronization with the base clock, a second synchronization signal for synchronizing the base clock and the system clock.

### CROSS-REFERENCE TO RELATED APPLICATIONS

The disclosure of Japanese Patent Application No. 2011-44819 filed on Mar. 2, 2011 including the specification, drawings and abstract is incorporated herein by reference in its entirety.

### FIELD OF THE INVENTION

The present invention relates to a clock synchronization circuit and a semiconductor integrated circuit. In particular, the invention relates to a clock synchronization circuit that generates a clock synchronization signal for synchronizing the base clock and the system clock.

### BACKGROUND OF THE INVENTION

Demand for faster central processing units (CPUs) has been increasing over the years. The base clock frequency of CPUs is ever increasing accordingly. To achieve faster CPUs, the process in CPUs has been made finer, and the operating voltage of CPUs has been reduced. Under these circumstances, it is more important to design the timings in consideration of the delay variation in the chip.

On the other hand, semiconductor integrated circuits are moving to system on chip (SoC), where a CPU, buses, a memory, and a controller such as a communication module are integrated into the same chip. The reason is that SoC, where one chip is equipped with advanced functions, has many advantages such as reduced footprints followed by system miniaturization, reductions in power consumption due to miniaturization, and reductions in parts count.

SoC requires that data be transmitted or received between the CPU and the controller, device, or the like. These elements are thus coupled together via a bus. Specifically, as shown in FIG. 2, a CPU and a USB (universal serial bus) module, a UART (universal asynchronous receiver transmitter) module, and the like are coupled together via a bus. In the configuration shown in FIG. 2, the CPU serves as a bus master, and the USB module and the UART module serve as slave devices.

While the base clock frequency of CPUs is ever increasing as described above, the speed of the system clock driving the bus is not required to be as high as the base clock of the CPU. The system clock is thus set to a frequency lower than the base clock. However, to transmit or receive data efficiently, the base clock and the system clock need be synchronized.

FIG. 3 is a diagram showing an example of timings of a base clock CLK, a system clock SYS_CLK, and data transfer. For example, with regard to timings of data transfer shown in FIG. 3, the CPU outputs data at a rising edge of the base clock, and the slave device coupled to the bus captures the data at a rising edge of the system clock SYS_CLK supplied to the bus. If the base clock CLK and the system clock SYS_CLK are not synchronized, the data may not be obtained. More specifically, if the timings of the rising edges of both clocks fall outside the period between t1 and t2 shown in FIG. 3, the data cannot properly be transferred.

Japanese Patent No. 3739431 discloses a circuit that generates a clock synchronization signal for synchronizing the base clock and the system clock. FIG. 4 shows the clock synchronization signal generation circuit disclosed in Japanese Patent No. 3739431 (FIG. 4 of Japanese Patent No. 3739431). The clock synchronization signal generation circuit disclosed in Japanese Patent No. 3739431 receives a base clock CLK and outputs a clock synchronization signal CLKEN for synchronizing the base clock CLK and a system clock SYS_CLK. The timing of the output of the clock synchronization signal CLKEN is changed according to the division ratio of the system clock SYS_CLK.

ARM Ltd., “Cortex-A9 Technical Reference Manual,” Mar. 31, 2008, [online], searched on the Internet on Feb. 14, 2011, URL:http://infocenter.arm.com/help/topic/com.arm.doc.ddiO388e/DDI0388E_cortex_a9_r2p0_trm.pdf> discloses a CPU architecture that synchronizes the base clock and the system clock using a clock synchronization signal to make bus access.

### SUMMARY

The analysis below has been made from the viewpoint of the present invention.

SoC has a bus master and slave devices therein. The bus master needs a base clock CLK and a clock synchronization signal CLKEN, and the slave devices need a system clock SYS_CLK. SoC uses a clock generation circuit that generates a base clock CLK, a system clock SYS_CLK, and a clock synchronization signal CLKEN from a clock generated by a phase locked loop (PLL) circuit or the like. Details of the clock generation circuit will be described later.

The base clock CLK and the clock synchronization signal CLKEN generated by the clock generation circuit must keep timings at which the bus master can transmit or receive data properly when receiving these signals. Accordingly, the influence of the delay variation between the base clock CLK and the clock synchronization signal CLKEN must be reduced to a minimum. For this reason, the clock generation circuit is disposed adjacent to the bus master such as the CPU.

However, many of recent SoC have multiple bus masters therein, preventing disposition of the clock generation circuit adjacent to all the bus masters. This increases the length of the wiring between the bus masters and the clock generation circuit. When the length of the wiring between the bus masters and the clock generation circuit is increased, clock tree synthesis (CTS) is performed to eliminate the delay variation between the base clock CLK and the clock synchronization signal CLKEN, that is, a CTS buffer is inserted into the wiring for the base clock CLK. A repeater (buffer) may additionally be used to compensate for electrical attenuation.

However, use of multiple such CTS buffers or repeaters increases the delay variation in SoC. This disadvantageously prevents the keeping of the proper timings of the base clock CLK and the clock synchronization signal CLKEN, preventing proper transmission or reception of data.

Accordingly, there is desired a clock synchronization signal and semiconductor integrated circuit that eliminate the delay variation between the base clock and the clock synchronization signal.

According to one aspect of the present invention, there is provided a clock synchronization circuit. The clock synchronization circuit receives a base clock, a first synchronization signal for synchronizing the base clock and a system clock, and a selection signal containing information about the division ratio of the system clock, holds the first synchronization signal over a predetermined time on the basis of the selection signal, and outputs, in synchronization with the base clock, a second synchronization signal for synchronizing the base clock and the system clock.

According to another aspect of the present invention, there is provided a semiconductor integrated circuit. The semiconductor integrated circuit includes: the above-mentioned clock synchronization circuit; a clock generation circuit that generates the base clock, the first synchronization signal, and the system clock; and a bus master that operates on the basis of the base clock and the second synchronization signal.

According to the aspects of the present invention, there is provided a clock synchronization signal and a semiconductor integrated circuit that eliminate the delay variation between the base clock and the clock synchronization signal.

### BRIEF DESCRIPTION OF THE DRAWINGS

FIG. 1 is a diagram showing an outline of the embodiments of the present invention;

FIG. 2 is a diagram showing an example of the connection among a CPU and other devices in SoC;

FIG. 3 is a diagram showing an example of timings of a base clock, a system clock, and transfer data;

FIG. 4 is a circuit diagram showing a circuit for generating a clock synchronization signal according to the related art;

FIG. 5 is a diagram showing an example of the internal configuration of a clock generation circuit;

FIG. 6 is a diagram showing an example of a waveform obtained when a base clock and a system clock have the same cycles in the clock generation circuit shown in FIG. 5;

FIG. 7 is a diagram showing an example of a waveform obtained when the division ratio of the system clock is 1/2 in the clock generation circuit shown in FIG. 5;

FIG. 8 is a diagram showing an example of a waveform obtained when the division ratio of the system clock is 1/3 in the clock generation circuit shown in FIG. 5;

FIG. 9 is a diagram showing an example of a waveform obtained when the division ratio of the system clock is 1/4 in the clock generation circuit shown in FIG. 5;

FIG. 10 is a diagram showing an example of the connection among a bus master, slave devices, and a clock generation circuit in SoC;

FIG. 11 is a diagram showing the relationship between a gating clock and a system clock;

FIG. 12 is a diagram showing the relationship between the disposition of the CPU and the clock generation circuit, and a clock branch point in SoC;

FIG. 13 is a diagram showing CTS performed on the wiring for the base clock between the CPU and the clock generation circuit;

FIG. 14 is a diagram showing an example of the internal configuration of a clock synchronization circuit according to a first embodiment of the present invention;

FIG. 15 is a diagram showing input/output timings of each signal obtained when a base clock and a system clock have the same cycles;

FIG. 16 is a diagram showing input/output timings of each signal obtained when the division ratio of the system clock is 1/2;

FIG. 17 is a diagram showing input/output timings of each signal obtained when the division ratio of the system clock is 1/3;

FIG. 18 is a diagram showing input/output timings of each signal obtained when a CLKEN_CTRL signal is changed;

FIG. 19 is a diagram showing an example of the internal configuration of a semiconductor integrated circuit including the clock synchronization circuit shown in FIG. 14;

FIG. 20 is a diagram showing an example of the internal configuration of a semiconductor integrated circuit including multiple clock synchronization circuits;

FIG. 21 is a timing chart showing an example of output timings of each signal in the semiconductor integrated circuit shown in FIG. 20;

FIG. 22 is a diagram showing an example of the internal configuration of a semiconductor integrated circuit according to a second embodiment of the present invention;

FIG. 23 is a timing chart showing an example of output timings of each signal in the semiconductor integrated circuit shown in FIG. 22;

FIG. 24 is a diagram showing an example of the internal configuration of a semiconductor integrated circuit according to a third embodiment of the present invention; and

FIG. 25 is a timing chart showing an example of output timings of each signal in the semiconductor integrated circuit shown in FIG. 24.

### DETAILED DESCRIPTION OF THE PREFERRED EMBODIMENTS

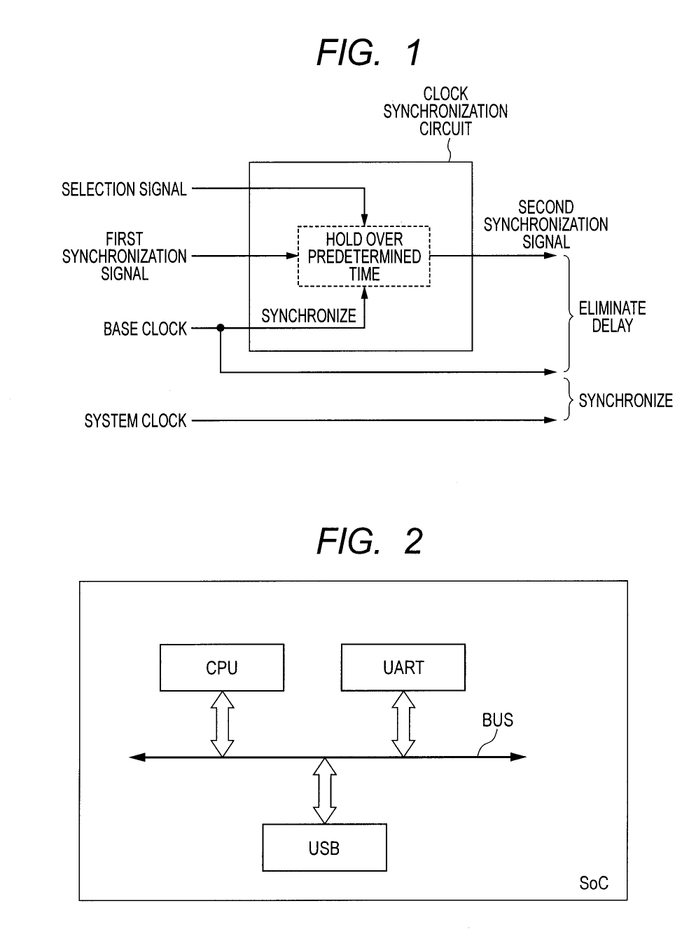

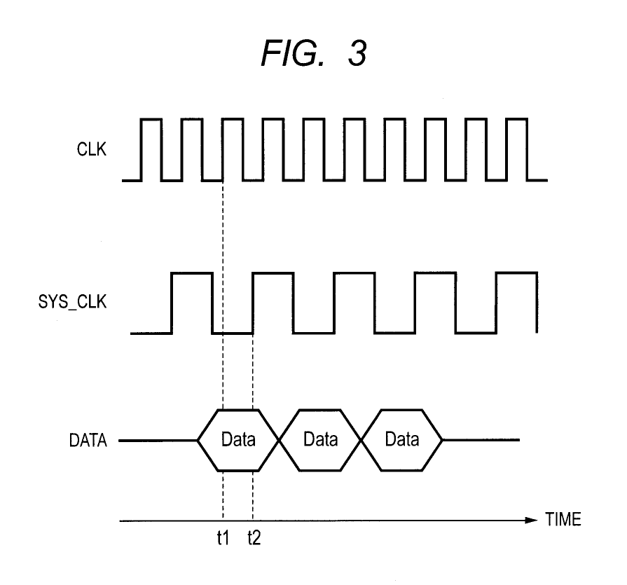

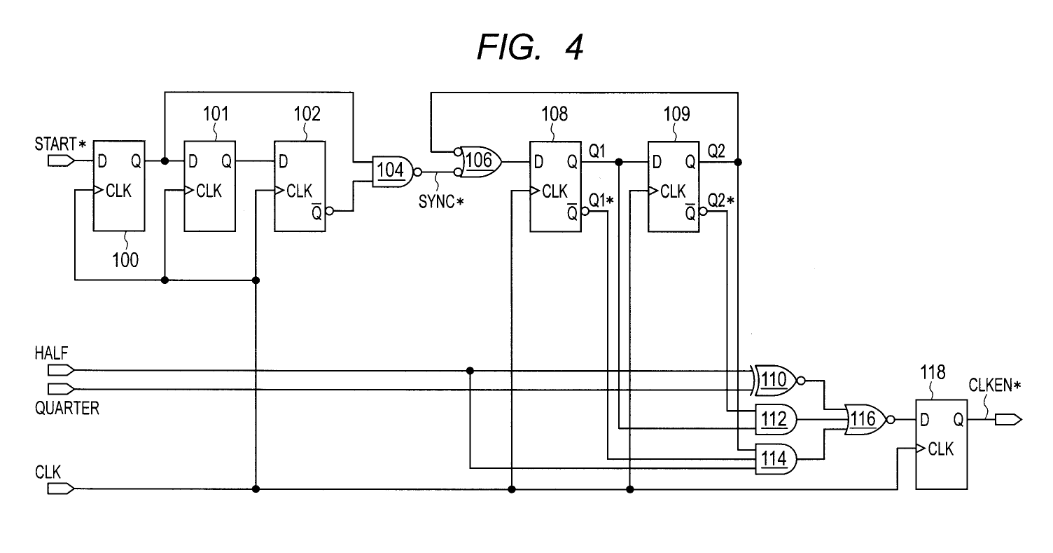

First, the embodiments of the present invention will be outlined with reference to FIG. 1. Reference numerals used in the drawing are assigned to elements for convenience sake to facilitate the understanding of the present invention but not intended to limit the invention to the illustrated aspect.

As described above, if the length of the wiring between a bus master and a clock generation circuit is increased, multiple CTS buffers or repeaters must be disposed. The amount of delay caused by a CTS buffer or repeater varies within a given range. Use of multiple such CTS buffers or repeaters increases the delay variation in SoC. This prevents the keeping of proper timings of the base clock CLK and the clock synchronization signal CLKEN. Accordingly, there is desired a clock synchronization signal and semiconductor integrated circuit that eliminate the delay variation between the base clock CLK and the clock synchronization signal CLKEN.

In view of the foregoing, a clock synchronization signal shown in FIG. 1 is provided. The clock synchronization circuit shown in FIG. 1 receives a base clock, a first synchronization signal for synchronizing the base clock and a system clock, and a selection signal containing information about the division ratio of the system clock, holds the first synchronization signal over a predetermined time on the basis of the selection signal, and outputs, in synchronization with the base clock, a second synchronization signal for synchronizing the base clock and the system clock.

The clock synchronization circuit shown in FIG. 1 receives the first synchronization signal for synchronizing the base clock and the system clock. The clock synchronization circuit, which has received the base clock and the first synchronization signal, holds the first synchronization signal over the predetermined time on the basis of the information contained in the selection signal so as to synchronize the first synchronization signal with the base clock, and outputs the held first synchronization signal as the second synchronization signal. As seen above, when a delay variation (skew) occurs between the base clock and the first synchronization signal, the clock synchronization circuit outputs the second synchronization signal, which is in synchronization with the base clock. Thus, there is no delay variation between the base clock and the second synchronization signal.

The clock synchronization circuit determines the time over which it holds the first synchronization signal, on the basis of the division ratio of the system clock. The first synchronization signal is originally generated on the basis of the division ratio of the system clock. Accordingly, if the clock synchronization circuit delays the first synchronization signal by a time period corresponding to a cycle of the first synchronization signal and then outputs the delayed first synchronization signal as the second synchronization signal, the base clock and the second synchronization signal are kept synchronized with each other.

By disposing at least one such clock synchronization circuit between the bus master and the clock generation circuit, the length of the wiring for the base clock and the clock synchronization signal between the clock branch point and the bus master is reduced. Thus, the influence of the delay variation in the chip can be reduced. As a result, the base clock and the system clock can be synchronized, so that data can properly be transmitted or received.

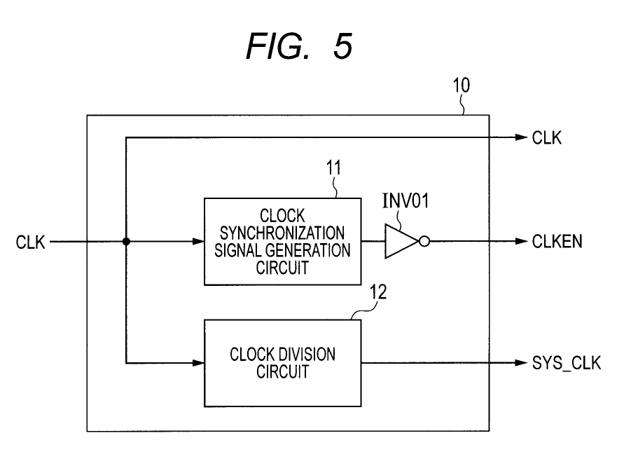

Next, a clock generation circuit that generates a base clock CLK, a system clock SYS_CLK, and a clock synchronization signal CLKEN in SoC will be described. Such a clock generation circuit can be formed using the clock synchronization signal generation circuit and the clock division circuit disclosed in Japanese Patent No. 3739431. FIG. 5 is a diagram showing an example of the internal configuration of a clock generation circuit 10. The clock generation circuit 10 shown in FIG. 5 receives a base clock CLK generated by a PLL circuit or the like, inverts an output signal of a clock synchronization signal generation circuit 11 disclosed in Japanese Patent No. 3739431 using an inverter INV01, and outputs the inverted signal as a clock synchronization signal CLKEN. The clock generation circuit 10 also receives the base clock CLK at a clock division circuit 12 and outputs it as a system clock SYS_CLK.

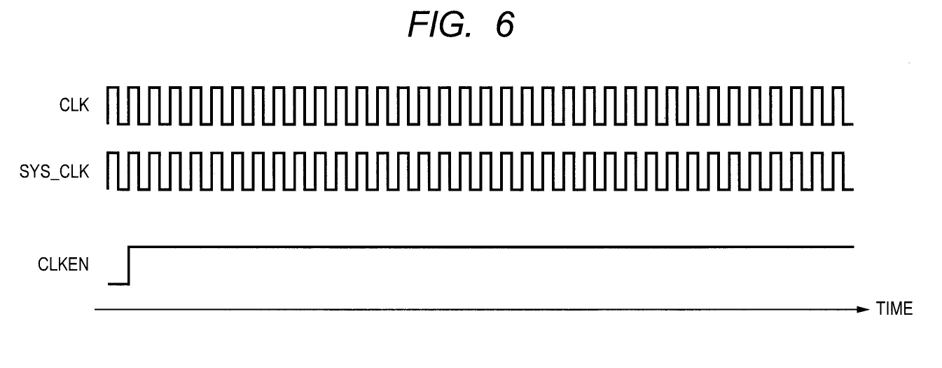

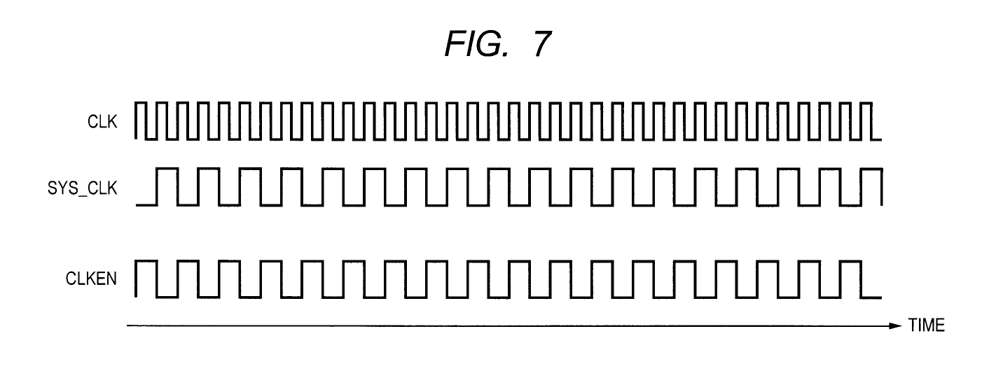

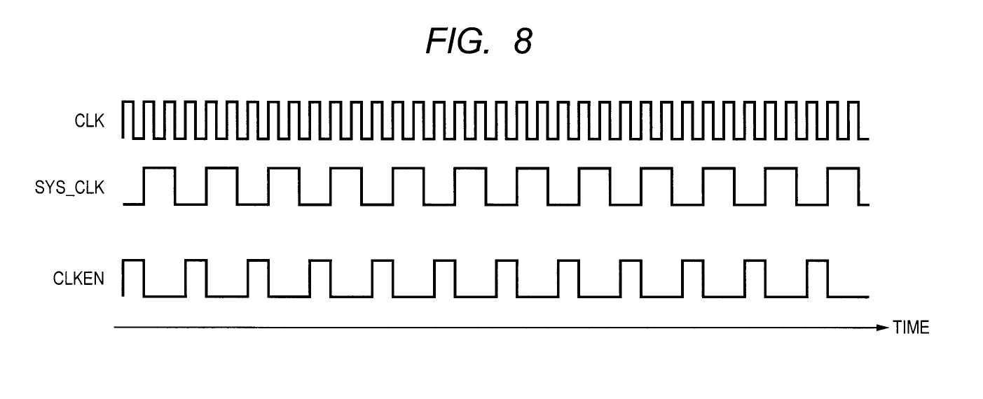

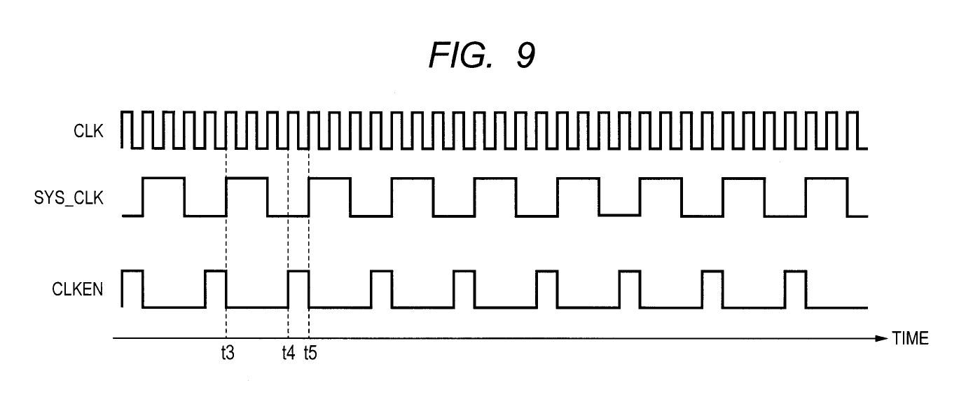

The clock generation circuit 10 changes the output timing of the clock synchronization signal CLKEN in accordance with the division ratio of the system clock SYS_CLK to the base clock CLK. FIGS. 6 to 9 are diagrams showing an example of an output waveform obtained when the clock generation circuit 10 changes the division ratio of the system clock SYS_CLK. FIG. 6 shows a waveform obtained when the base clock CLK and the system clock SYS_CLK have the same cycles. FIG. 7 shows a waveform obtained when the division ratio of the system clock SYS_CLK is 1/2. FIG. 8 shows a waveform obtained when the division ratio of the system clock SYS_CLK is 1/3. FIG. 9 shows a waveform obtained when the division ratio of the system clock SYS_CLK is 1/4. The waveforms of FIGS. 6 to 9 indicate that the base clock CLK and the system clock SYS_CLK are synchronized at respective rising edges and that the clock synchronization signal CLKEN becomes active prior to the timing when both clocks are synchronized. In the waveforms shown in FIGS. 6 to 9, the clock synchronization signals CLKEN are high active.

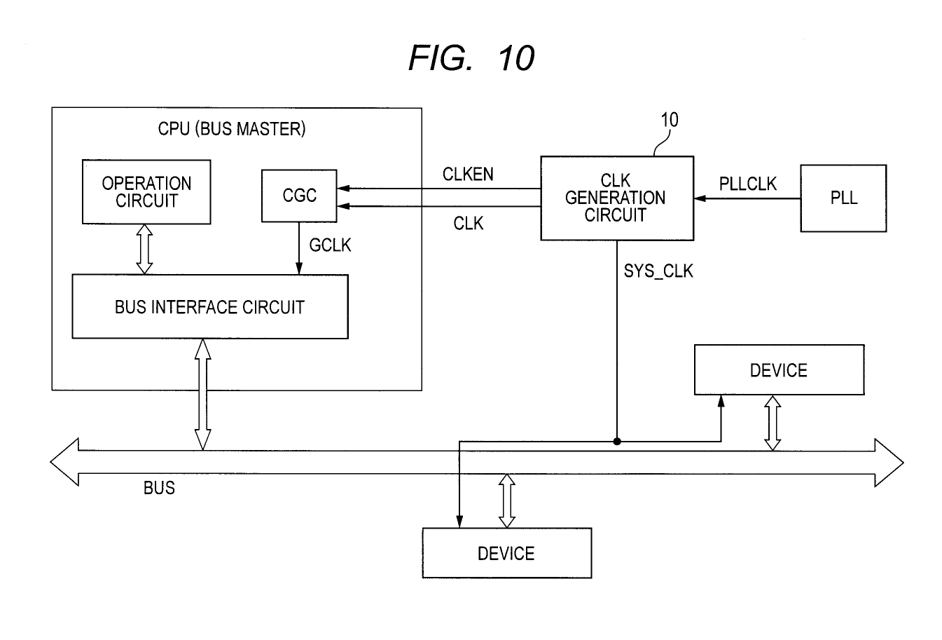

The relationship among the bus master, the slave devices, and the clock generation circuit in SoC will be described. FIG. 10 is a diagram showing an example of the connection among the bus master, the slave devices, and the clock generation circuit in SoC. In FIG. 10, a CPU serving as a bus master receives a base clock CLK and a clock synchronization signal CLKEN from the clock generation circuit, and the slave devices receive a system clock SYS_CLK therefrom. While the slave devices directly receive the system clock SYS_CLK from the clock generation circuit in FIG. 10, they may indirectly receive the system clock SYS_CLK supplied to the bus if SoC includes a control circuit such as a bus arbiter. In the following description, it is assumed that a system clock SYS_CLK is directly supplied to the bus.

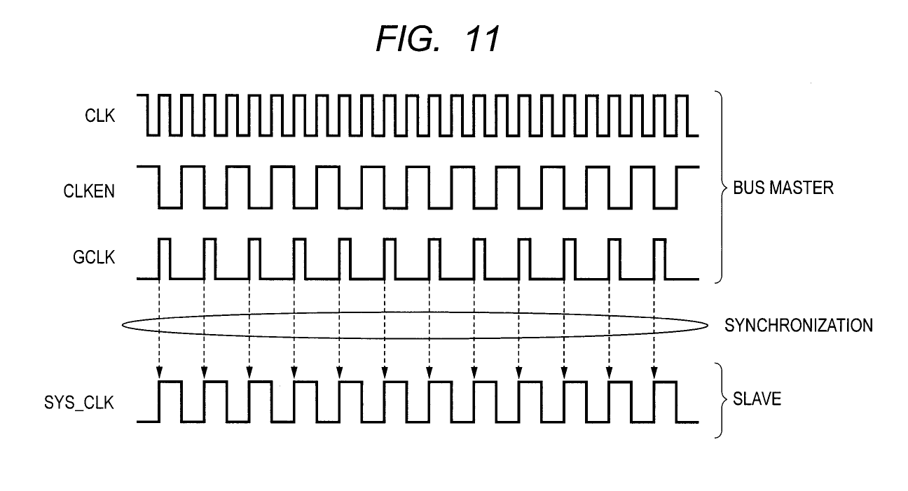

The CPU receives the base clock CLK and the clock synchronization signal CLKEN at a clock gating cell. The clock gating cell generates and supplies a gating clock GCLK to a bus interface circuit. This synchronizes the base clock CLK and the system clock SYS_CLK as well as reduces the power consumption of the bus interface circuit (FIG. 11). The above-mentioned configuration achieves the synchronization between the base clock CLK and the system clock SYS_CLK.

The waveforms of FIGS. 6 to 9 will be reexamined. The waveforms shown in FIGS. 6 to 9 indicate the timings of the signals outputted by the clock generation circuit 10. These timings must be kept until the point in time when the bus master and the slave devices receive the respective signals. From FIGS. 6 to 9, it is understood that the clock synchronization signal CLKEN becomes active at a rising edge of the base clock CLK one cycle before a rising edge thereof in synchronization with a rising edge of the system clock SYS_CLK. This means that the timing when the clock synchronization signal CLKEN can be made active depends on the cycles of the base clock CLK.

That is, when the clock synchronization signal CLKEN becomes active earlier than a rising edge of the base clock CLK one cycle before a rising edge thereof in synchronization with a rising edge of the system clock SYS_CLK, both clocks lose synchronization with each other in the bus master. For example, to synchronize the base clock CLK and the system clock SYS_CLK at time t5 in FIG. 9, the clock synchronization signal CLKEN must becomes active between times t4 and t5. If it becomes active before time t4, both clocks lose synchronization with each other in the bus master. Accordingly, even if the timings of the base clock CLK and the clock synchronization signal CLKEN are properly kept at the point in time when both signals are outputted by the clock generation circuit 10, the timings may be displaced from each other due to the influence of such as the wiring between the bus master and the clock generation circuit 10. In this case, data cannot be properly inputted or outputted.

As described above, CPUs have been speeded up significantly in recent years, increasing the base clock CLK. This has made it difficult to keep the timings of the base clock CLK and the clock synchronization signal CLKEN. On the other hand, the system clock SYS_CLK is slow compared to the base clock CLK, so the clock synchronization signal CLKEN is only required to become active between times t3 and t5. For this reason, the influence of the wiring between the clock generation circuit 10 and the slave device can be said to be smaller than that of the wiring between the bus master and the clock generation circuit 10. In view of the foregoing, properly transferring data requires keeping the timings of the base clock CLK and the clock synchronization signal CLKEN in the bus master.

Conceivable methods for keeping the timings of the base clock CLK and the clock synchronization signal CLKEN include disposition of the bus master and the clock generation circuit adjacent to each other.

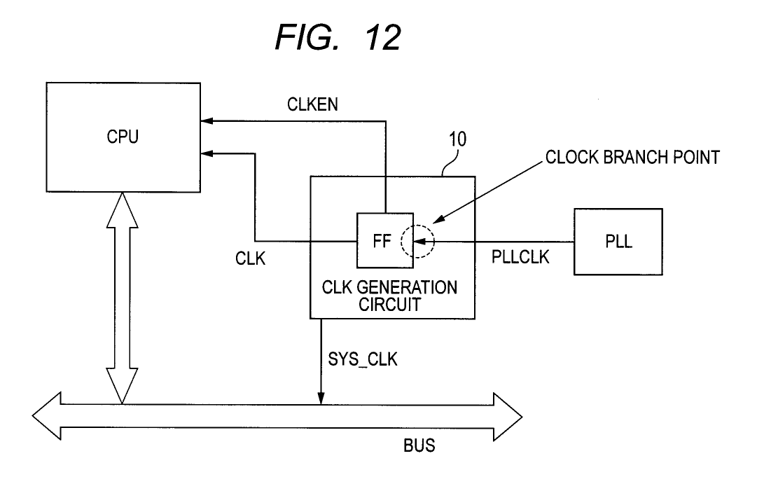

FIG. 12 is a diagram showing the relationship between the disposition of the CPU serving as the bus master and the clock generation circuit 10, and the clock branch point. As shown in FIG. 12, a base clock CLK generated by a PLL circuit is received by the clock generation circuit 10, and the base clock CLK and a clock synchronization signal CLKEN are synchronized by a flip-flop of the clock synchronization signal generation circuit disclosed in Japanese Patent No. 3739431. The base clock CLK and the clock synchronization signal CLKEN are then supplied to the CPU. If the CPU and the clock generation circuit are adjacent to each other, the influence of the wiring therebetween can be reduced. Thus, the influence of the delay variation between the base clock CLK and the clock synchronization signal CLKEN in the chip can be reduced to a minimum.

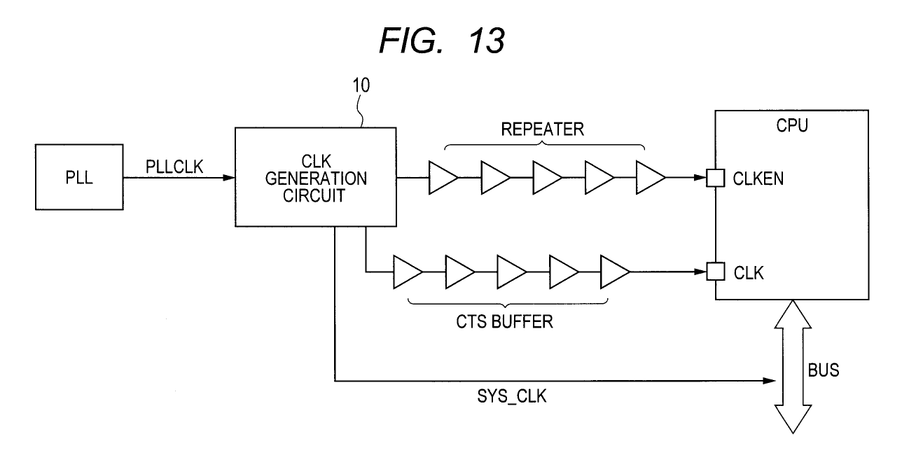

Meanwhile, SoC has included multiple bus masters in recent years. This has made it impossible to dispose the clock generation circuit 10 adjacent to all the bus masters. For this reason, as shown in FIG. 13, CTS is performed on the wiring for the base clock CLK between the CPU and the clock generation circuit. Thus, the timing when the CPU receives the base clock CLK and the clock synchronization signal CLKEN is adjusted. Where the wiring for the clock synchronization signal CLKEN is long, a repeater may be used.

On the other hand, the delay amount of the CTS buffer used in the wiring for the base clock CLK and that of the repeater used in the wiring for the clock synchronization signal CLKEN vary within a given range. Thus, use of multiple such CTS buffers and repeaters increases the delay variation in SoC. This may prevent the keeping of the proper timings of the base clock CLK and the clock synchronization signal CLKEN, preventing proper transmission or reception of data.

### First Embodiment

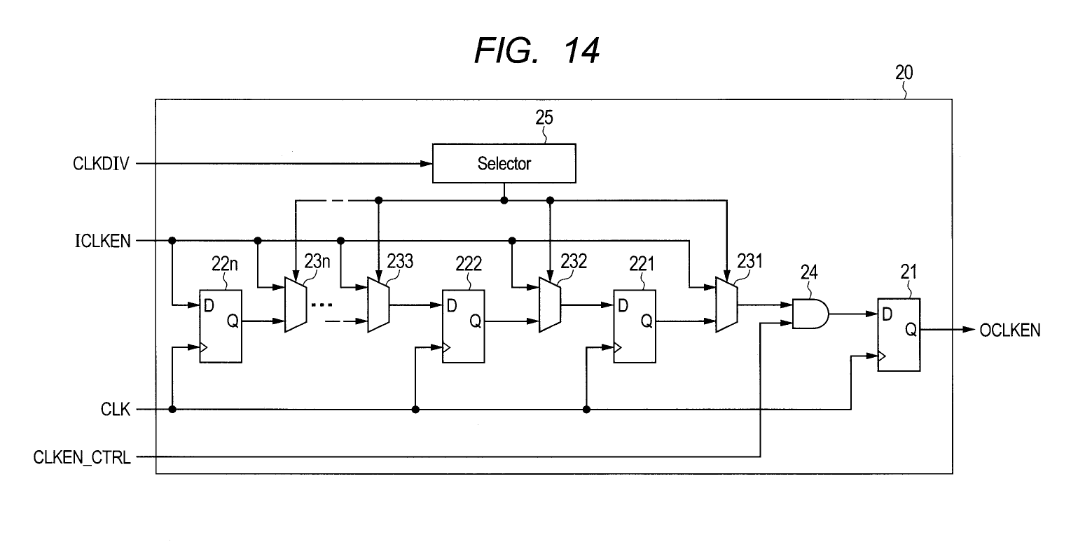

Now, a first embodiment of the present invention will be described in detail with reference to the drawings. FIG. 14 is a diagram showing an example of the internal configuration of a clock synchronization circuit 20 according to this embodiment.

The clock synchronization circuit 20 shown in FIG. 14 includes a flip-flop 21, flop-flops 221 to 22n (n being an integer of one or more, same for below), multiplexers 231 to 23n, an AND circuit 24, and a selector 25.

The clock synchronization circuit 20 receives a base clock CLK, a clock synchronization signal ICLKEN outputted by the clock generation circuit 10 (corresponding to a first synchronization signal), a CLKDIV signal containing information about the division ratio of the system clock, and a CLKEN_CTRL signal for controlling permission or stop of output of the clock synchronization circuit 20. The clock synchronization circuit 20 also outputs a clock synchronization signal OCLKEN (corresponding to a second synchronization signal).

The flip-flops 221 to 22n are coupled together in series via the multiplexers 231 to 23n, and the flip-flop 22n receives the clock synchronization signal ICLKEN. The data output terminals of the flip-flops 221 to 22n are coupled to input terminals of the multiplexers 231 to 23n, respectively.

The other input terminals of the multiplexers 231 to 23n are coupled to the clock synchronization signal ICLKEN. The outputs of the multiplexers 231 to 23n are selected in accordance with a control signal outputted by the selector 25.

The AND circuit 24 receives an output of the multiplexer 231 and the CLKEN_CTRL signal and outputs the operation result to a data input terminal of the flip-flop 21.

The flip-flop 21 receives the output of the AND circuit 24 at the data input terminal and outputs it from the data output terminal as the clock synchronization signal OCLKEN. The base clock CLK is inputted to the clock terminals of the flip-flop 21 and the flip-flops 221 to 22n.

The selector 25 receives the CLKDIV signal and selects the outputs of the multiplexers 231 to 23n on the basis of information contained in the CLKDIV signal. Specifically, when the base clock CLK and the system clock SYS_CLK have the same cycles, the selector 25 selects the clock synchronization signal ICLKEN as the input of the multiplexer 231. When the division ratio of the system clock SYS_CLK is 1/2, the selector 25 selects the data output of the flip-flop 221 as the input of the multiplexer 231 and the clock synchronization signal ICLKEN as the input of the multiplexer 232. When the division ratio of the system clock SYS_CLK is 1/3, the selector 25 selects the data output of the flip-flop 221 as the input of the multiplexer 231, the data output of the flip-flop 222 as the input of the multiplexer 232, and the clock synchronization signal ICLKEN as the input of the multiplexer 233. As seen above, the output of each multiplexer is selected in accordance with the division ratio of the system clock SYS_CLK.

The respective numbers of the flip-flops 221 to 22n and the multiplexers 231 to 23n are determined by the division ratio of the system clock SYS_CLK. For example, where the division ratio of the system clock SYS_CLK up to one-fourth need be addressed, four stages of flip-flops are coupled together in series.

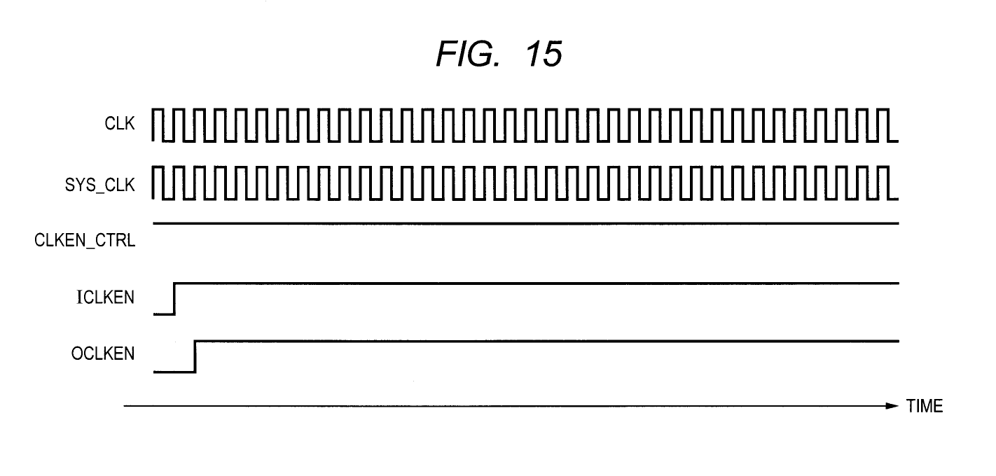

Now, the operation of the clock synchronization circuit 20 will be described. FIG. 15 is a diagram showing input/output timings of each signal obtained when the base clock CLK and the system clock SYS_CLK are the same (division ratio: 1/1).

Since the division ratio is 1/1, the clock synchronization signal ICLKEN is selected as the input of the multiplexer 231. Since the CLKEN_CTRL signal is an H level, the AND circuit 24 does not interrupt the output of the multiplexer 231. The flip-flop 21 then delays the clock synchronization signal ICLKEN received via the multiplexer 231 and the AND circuit 24 by a time period corresponding to one cycle of the base clock CLK and outputs the delayed signal as a clock synchronization signal OCLKEN.

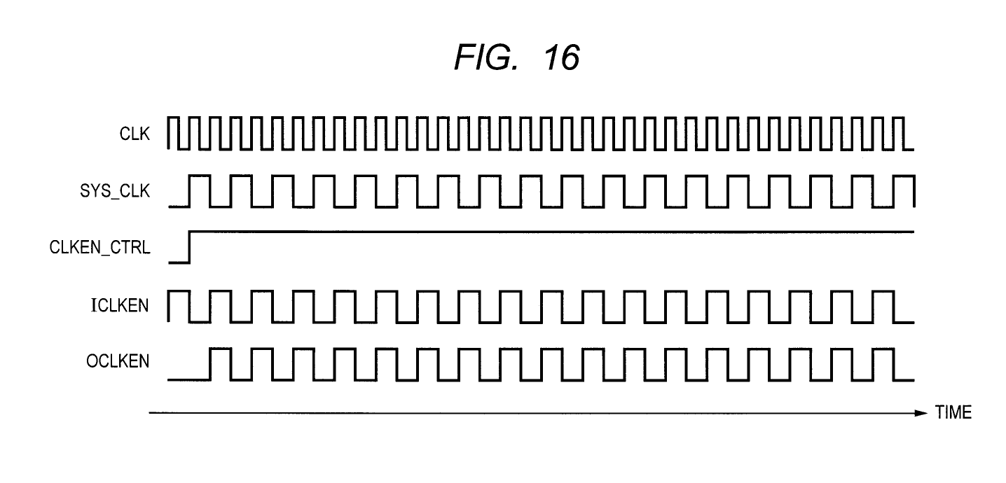

FIG. 16 is a diagram showing input/output timings of each signal obtained when the division ratio of the system clock SYS_CLK is 1/2. Since the division ratio is 1/2, the data output of the flip-flop 221 is selected as the input of the multiplexer 231, and the clock synchronization signal ICLKEN as the input of the multiplexer 232. As a result, the clock synchronization signal ICLKEN is delayed by the flip-flop 221 and the flip-flop 21 by a time period corresponding to two cycles of the base clock CLK and outputted as a clock synchronization signal OCLKEN.

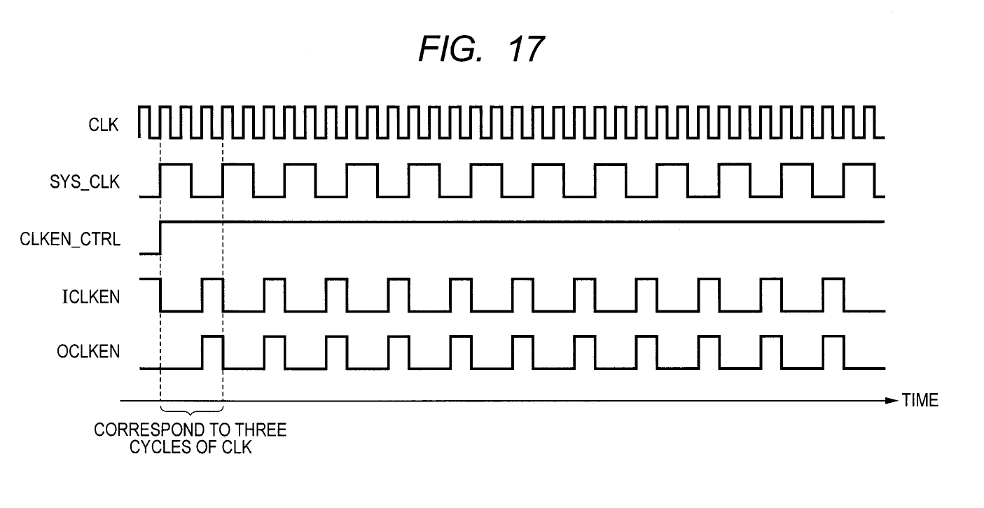

Similarly, where the division ratio of the system clock SYS_CLK is 1/3, the clock synchronization signal ICLKEN is delayed by the flip-flops 221 and 222 and the flip-flop 21 by a time period corresponding to three cycles of the base clock CLK and outputted as a clock synchronization signal OCLKEN (FIG. 17).

As seen above, the clock synchronization signal ICLKEN is delayed by a time period obtained by multiplying the cycle of the base clock CLK by the division ratio and outputted as a clock synchronization signal OCLKEN. The time period by which the clock synchronization signal ICLKEN is delayed corresponds to one cycle of the clock synchronization signal ICLKEN. For example, the waveforms shown in FIG. 17 represent a case when the division ratio of the system clock SYS_CLK is 1/3. The clock synchronization signal ICLKEN here is delayed by a time period corresponding to three cycles of the base clock CLK. This time period is equal to one cycle of the clock synchronization signal ICLKEN.

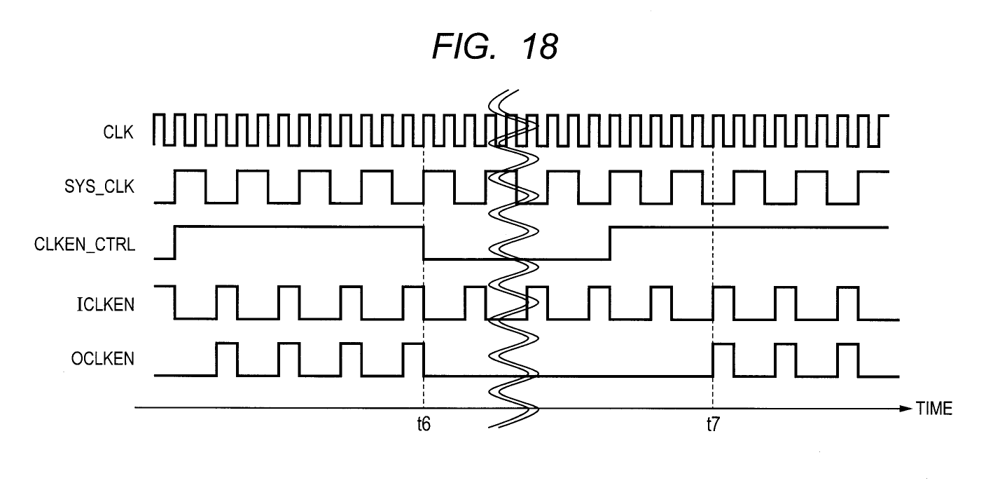

FIG. 18 is a diagram showing input/output timings of each signal obtained when the CLKEN_CTRL signal is changed. When the CLKEN_CTRL signal is set to an L level, the output of the AND circuit 24 becomes an L level. The clock synchronization signal OCLKEN also becomes an L level accordingly (time t6). When the CLKEN_CTRL signal is set to an H level again, the output of the clock synchronization signal OCLKEN is also restored (time t7).

The layout of SoC using the clock synchronization circuit 20 will be described. As described above, SoC has often included multiple bus masters in recent years. This makes it impossible to dispose the clock generation circuit 10 adjacent to all the bus masters. As a result, the length of the wiring between the bus master and the clock generation circuit 10 is increased, making it difficult to keep the timings of the base clock CLK and the clock synchronization signal CLKEN.

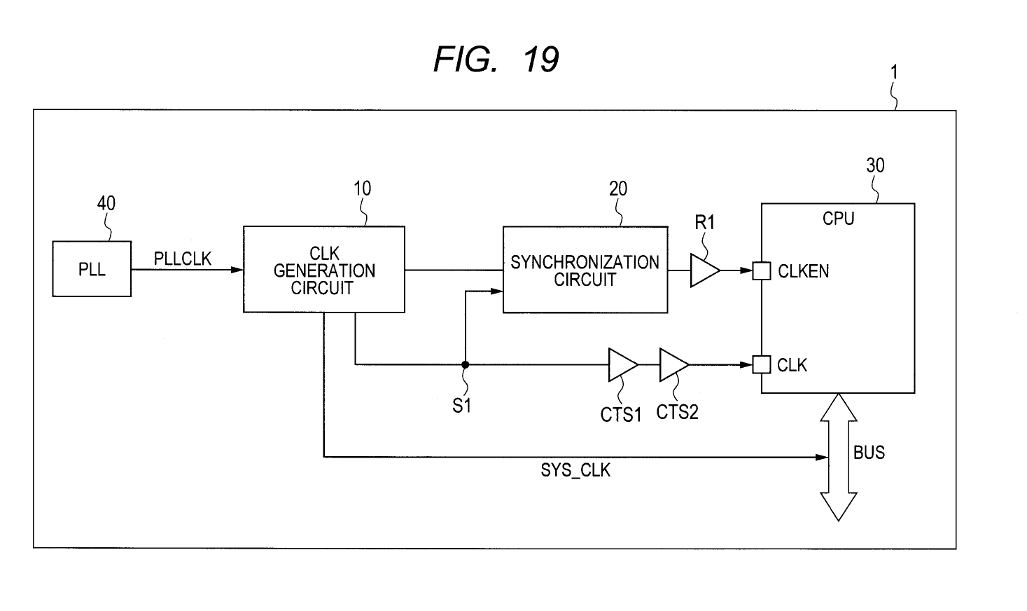

For this reason, the clock synchronization circuit 20 is disposed adjacent to each bus master to eliminate the delay variation between the base clock CLK and the clock synchronization signal CLKEN. FIG. 19 is a diagram showing an example of the internal configuration of a semiconductor integrated circuit 1 including the clock synchronization circuit 20.

The semiconductor integrated circuit 1 shown in FIG. 19 includes the clock generation circuit 10, the clock synchronization circuit 20, a CPU 30, a PLL circuit 40, a repeater R1, and CTS buffers CTS1 and CTS2.

The clock generation circuit 10 is the circuit described with reference to FIG. 5. The clock generation circuit 20 is the circuit described with reference to FIG. 14. Accordingly, these circuits will not be described.

The CPU 30 functions as a bus master in the semiconductor integrated circuit 1. The PLL circuit 40 generates a base clock CLK and supplies it to the clock generation circuit 10.

The semiconductor integrated circuit 1 shown in FIG. 19 has the clock synchronization circuit 20 between the CPU 30 and the clock generation circuit 10. By disposing the clock synchronization circuit 20 adjacent to the CPU 30, the length of the wiring for the clock synchronization signal CLKEN from the clock branch point can be reduced. Thus, the influence of the delay variation in the chip can be reduced.

This is because a clock synchronization signal CLKEN generated by the clock generation circuit 10 is synchronized with the base clock CLK by the flip-flop 21 of the clock synchronization circuit 20 and outputted. Accordingly, a branch point S1, located on the wiring for the base clock CLK between the CPU 30 and the clock generation circuit 10, serves as the base point of the delay variation between the base clock CLK and the clock synchronization signal CLKEN. The range of delay variation between both signals becomes narrower as the branch point S1 is closer to the CPU 30.

If the range of the delay variation is narrowed, it is possible to keep the timing when the base clock CLK and the clock synchronization signal CLKEN reach the CPU 30 by performing CTS on the wiring between the CPU 30 and the clock synchronization circuit 20 and inserting a repeater into the wiring.

Even if the timings of the base clock CLK and the clock synchronization signal CLKEN cannot be kept using a single clock synchronization circuit 20, the timings of both signals can be kept by using multiple clock synchronization circuits 20.

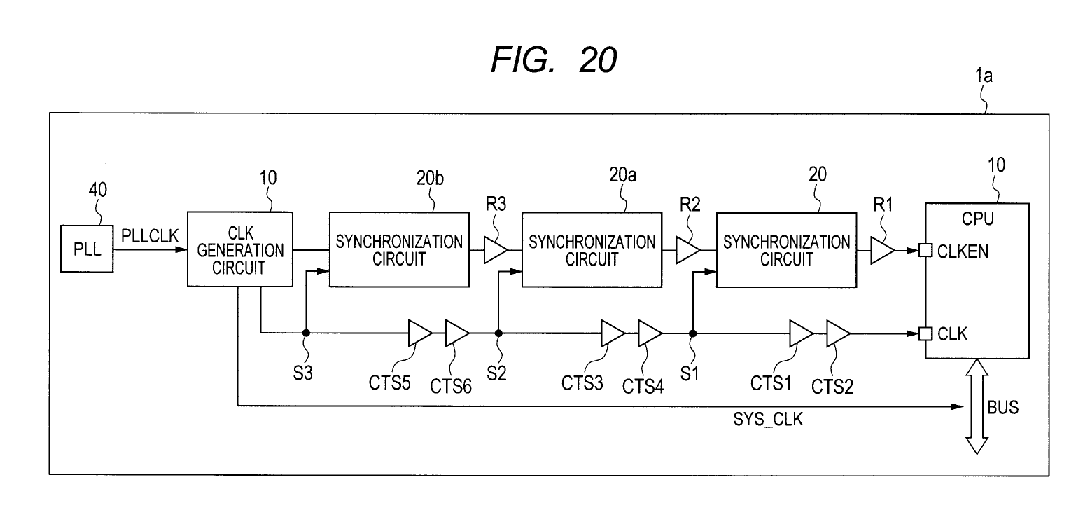

FIG. 20 is a diagram showing an example of the internal configuration of a semiconductor integrated circuit 1a having multiple clock synchronization circuits 20 disposed thereon. In the semiconductor integrated circuit 1a shown in FIG. 20, assume that the CPU 30 and the clock generation circuit 10 are disposed apart from each other. Thus, assume that it is impossible to keep the timings of the base clock CLK and the clock synchronization signal CLKEN using a single clock synchronization circuit 20. In such a case, multiple clock synchronization circuits 20 are disposed between the clock generation circuit 10 and the CPU 30.

As a result, the clock branch points S1 to S3 serve as the base points of the delay variation between the base clock CLK and the clock synchronization signal CLKEN. For this reason, by performing CTS between the clock synchronization circuits (20, 20a, 20b), it is possible to supply both signals to the CPU 30 while keeping the timings of both signals.

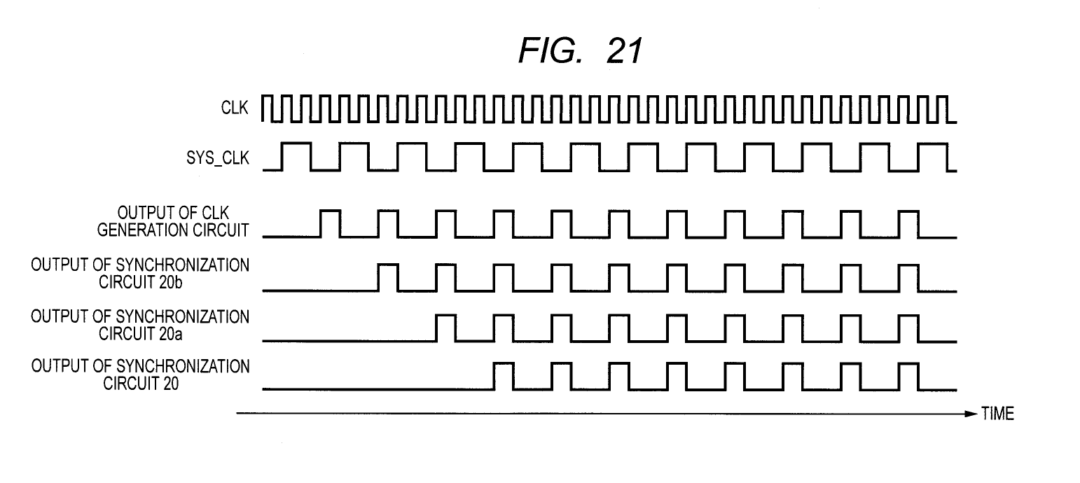

FIG. 21 is a timing chart showing an example of input/output of each signal in the semiconductor integrated circuit 1a shown in FIG. 20. As shown in FIG. 21, a clock synchronization signal CLKEN is delayed in accordance with the number of stages of the coupled clock synchronization circuit 20 and then supplied to the CPU 30. Here, each of the clock synchronization circuits (20, 20a, 20b) receives a clock synchronization signal ICLKEN, and outputs a clock synchronization signal OLKEN while keeping synchronization between the received clock synchronization signal ICLKEN and a base clock CLK. Thus, the base clock CLK and the system clock SYS_CLK can be properly synchronized.

As seen above, by disposing at least one such clock synchronization circuit between the bus master and the clock generation circuit, the length of the branch bus for the clock synchronization signal CLKEN is reduced. Thus, the influence of the delay variation in the chip can be reduced. As a result, the base clock CLK and the system clock SYS_CLK can be synchronized, so data can properly be transmitted or received.

### Second Embodiment

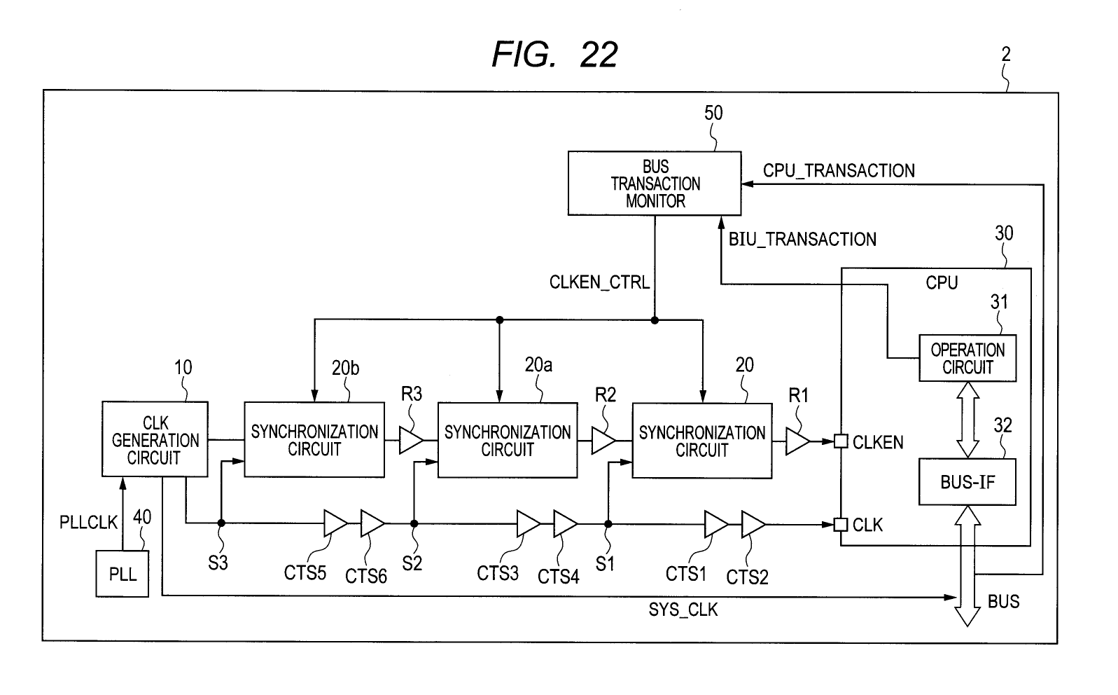

Next, a second embodiment of the present invention will be described in detail with reference to the drawings. FIG. 22 is a diagram showing an example of the internal configuration of a semiconductor integrated circuit 2 according to this embodiment. In FIG. 22, the same elements as those in FIG. 20 are assigned the same reference numerals and will not be described.

The semiconductor integrated circuit 2 differs from the semiconductor integrated circuit 1a shown in FIG. 20 in that it includes a bus transaction monitor 50. The bus transaction monitor 50 receives a BIU_TRANSACTION signal issued by an operation circuit 31 of the CPU 30 and a CPU_TRANSACTION signal indicating whether there is a transaction on the bus.

The fact that the BIU_TRANSACTION signal is set to an H level means that a data transmission/reception instruction has been sent by the operation circuit 31 via a bus interface circuit 32. The fact that the CPU_TRANSACTION signal is set to an H level means that the bus is occupied for transmission or reception of data.

The bus transaction monitor 50 outputs a CLKEN_CTRL signal to the clock synchronization circuits (20, 20a, 20b). When both the BIU_TRANSACTION and CPU_TRANSACTION signals are an L level, the bus transaction monitor 50 determines that there no data to be transmitted or received on the bus and sets the CLKEN_CTRL signal to an L level.

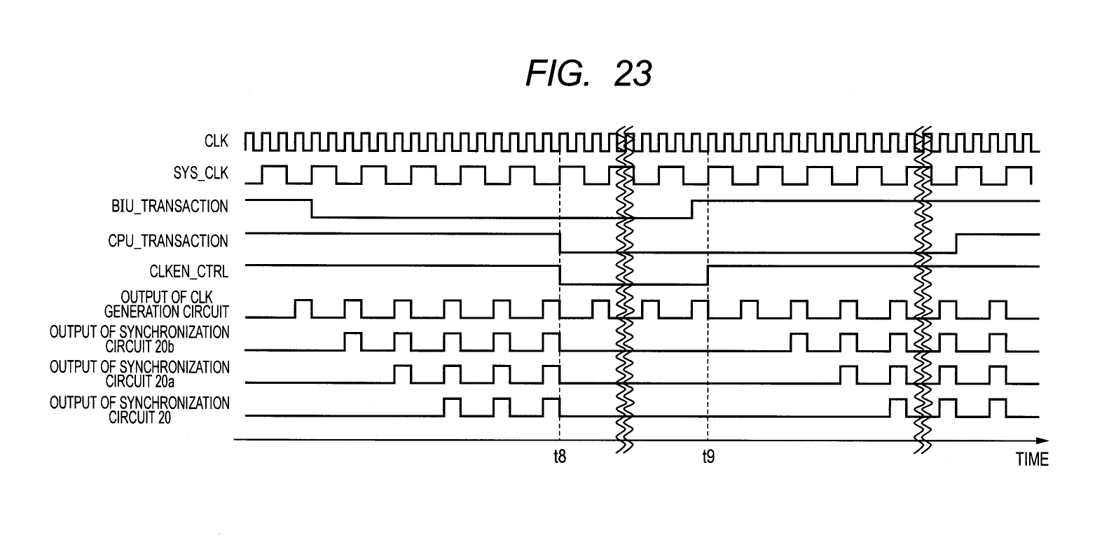

FIG. 23 is a timing chart showing an example of input/output of each signal in the semiconductor integrated circuit 2 shown in FIG. 22. The operation of the semiconductor integrated circuit 2 will be described with reference to FIG. 23.

For example, when the cache is hit in the CPU 30, there is no need to access the bus. Thus, the BIU_TRANSACTION and CPU_TRANSACTION signals become an L level (time t8). When the BIU_TRANSACTION and CPU_TRANSACTION signals are set to an L level, the bus transaction monitor 50 sets the CLKEN_CTRL signal to an L level. When the CLKEN_CTRL signal is set to an L level, the clock synchronization circuits (20, 20a, 20b) stop outputting the clock synchronization signal OCLKEN (FIG. 18).

When the clock synchronization signal OCLKEN is set to an L level, the clock gating cell does not generate a gating clock GCLK, and the bus interface circuit 32 stops accessing the bus.

When both the BIU_TRANSACTION and CPU_TRANSACTION signals are a level other than an L level, there is data to be transmitted or received on the bus. Thus, the CLKEN_CTRL signal is set to an H level (time t9).

As seen above, the clock synchronization signal OCLKEN becomes active only when there is a need to access the bus in the semiconductor integrated circuit 2. Thus, the power for operating the bus interface circuit 32 can be reduced.

### Third Embodiment

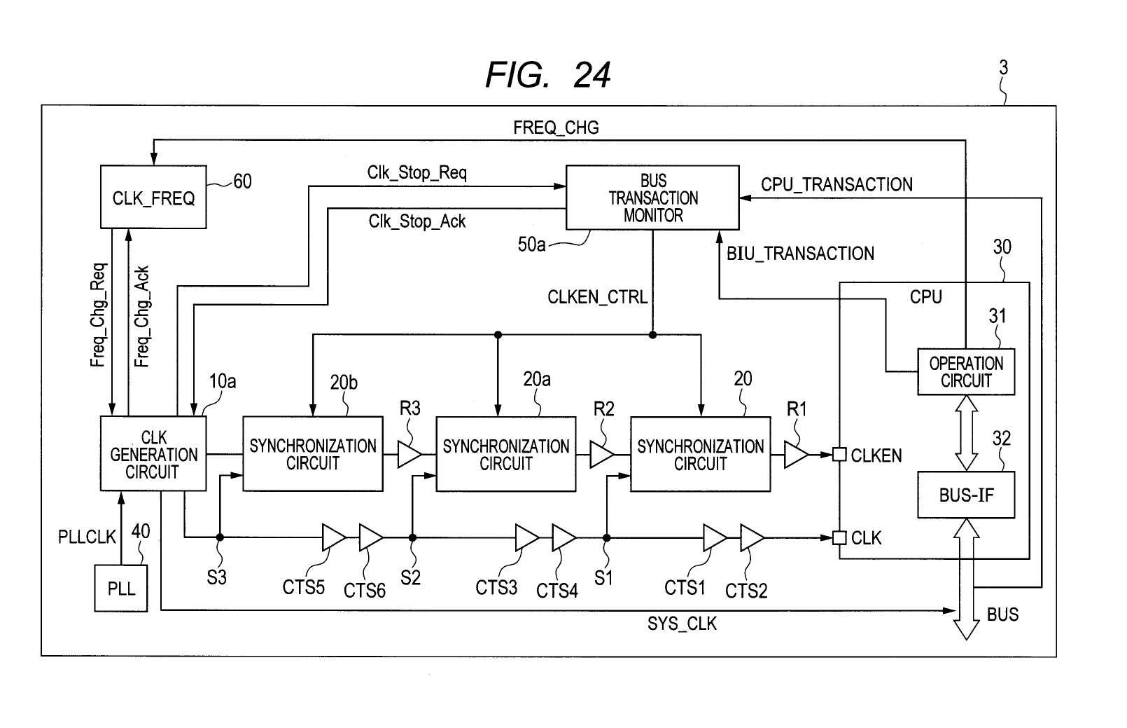

A third embodiment of the present invention will be described in detail with reference to the drawings. FIG. 24 is a diagram showing an example of the internal configuration of a semiconductor integrated circuit 3 according to this embodiment. In FIG. 24, the same elements as those in FIG. 22 are assigned the same reference numerals and will not be described.

The semiconductor integrated circuit 3 differs from the semiconductor integrated circuit 2 in that it includes a clock frequency change sequencer 60.

The clock frequency change sequencer 60 receives a FREQ_CHG signal outputted by the operation circuit 31 of the CPU 30. Using the FREQ_CHG signal, the CPU 30 requests the clock frequency change sequencer 60 to change the frequency (division ratio) of the system clock SYS_CLK.

A clock generation circuit 10a and the clock frequency change sequencer 60 perform a handshake for changing the frequency of the system clock SYS_CLK using Freq_Chg_Req and Freq_Chg_Ack signals. The clock generation circuit 10a and a bus transaction monitor 50a also perform a handshake using Clk_Stop_Req and Clk_Stop_Ack signals.

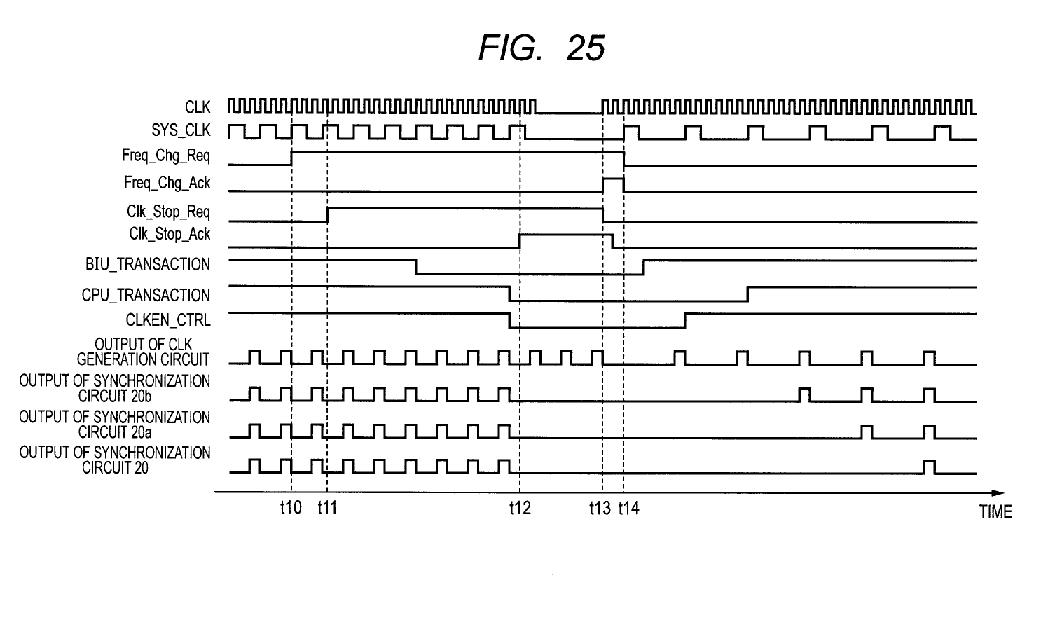

FIG. 25 is a timing chart showing an example of input/output of each signal in the semiconductor integrated circuit 3. The operation of the semiconductor integrated circuit 3 will be described with reference to FIG. 25. Where the CPU 30 changes the frequency of the system clock SYS_CLK, it issues a FREQ_CHG signal to the clock frequency change sequencer 60. The clock frequency change sequencer 60 receives the FREQ_CHG signal and asserts a Freq_Chg_Req signal to request the clock generation circuit 10a to change the frequency (time t10).

The clock generation circuit 10a receives the Freq_Chg_Req signal and asserts a Clk_Stop_Req signal to request the bus transaction monitor 50a to stop the clock (time t11).

When both BIU_TRANSACTION and CPU_TRANSACTION signals are an L level, the bus transaction monitor 50a sets a CLKEN_CTRL signal to an L level. When the CLKEN_CTRL signal is set to an L level, the no clock synchronization signal OCLKEN is outputted, and the bus interface circuit 32 stops data transfer. The bus transaction monitor 50a then asserts a Clk_Stop_Ack signal (time t12).

When the Clk_Stop_Ack signal is asserted, the clock generation circuit 10a stops outputting the system clock SYS_CLK. Subsequently, the clock generation circuit 10a changes the frequency of the system clock SYS_CLK and then asserts a Freq_Chg_Ack signal and deasserts the Clk_Stop_Req signal (time t13).

When the Freq_Chg_Ack signal is asserted, the clock frequency change sequencer 60 deasserts the Freq_Chg_Req signal and waits for the Freq_Chg_Ack signal to be deasserted. When the Freq_Chg_Ack signal is deasserted, the frequency change sequence of the system clock SYS_CLK completes (time t14). The bus transaction monitor 50 waits for the Clk_Stop_Req signal to be deasserted and, upon deassertion thereof, deasserts the Clk_Stop_Ack signal.

While the case where the CPU 30 issues a request for changing the frequency of the system clock SYS_CLK has been described in this embodiment, the present invention is not limited to such a case. Another circuit or the like may issue a request for changing the frequency of the system clock SYS_CLK.

As described above, in this embodiment, the clock frequency change sequencer 60 and the bus transaction monitor 50a are used to change the system clock SYS_CLK in a situation where there is no transaction on the bus. Since the clock frequency change sequencer 60 and the bus transaction monitor 50a handle the frequency change sequence of the system clock SYS_CLK, a rapid frequency change in the system clock SYS_CLK by hardware is realized.

In contrast, where the CPU 30 directly changes the frequency of the system clock SYS_CLK, changing the system clock SYS_CLK requires restricting the operation of the CPU 30 using a SLEEP command or the like. The reason is that when the frequency of the system clock SYS_CLK is changed during access to the bus by the CPU 30 without using a SLEEP command or the like, the base clock CLK and the system clock SYS_CLK go out of synchronization with each other, thereby failing to transmit or receive data properly. For this reason, changing the frequency of the system clock SYS_CLK by software requires executing a SLEEP command or the like. That is, it takes time to change the system clock SYS_CLK.

The disclosures of the above-mentioned related-art examples are incorporated herein by reference. Various changes and modifications can be made to the above-mentioned embodiments without departing from the spirit and scope of the present invention. Further, the disclosed elements can be combined or selected without departing from the spirit and scope of the invention. That is, the present invention will of course include various changes and modifications that those skilled in the art can make to the embodiments departing from the spirit and scope thereof.

What is claimed is:

1. A clock synchronization circuit,
wherein the clock synchronization circuit receives a base clock, a first synchronization signal for synchronizing the base clock and a system clock, and a selection signal containing information about the division ratio of the system clock, holds the first synchronization signal over a predetermined time on the basis of the selection signal, and outputs, in synchronization with the base clock, a second synchronization signal for synchronizing the base clock and the system clock.

2. The clock synchronization circuit according to claim 1, further comprising:
n stages of series-coupled holding circuits that each receive data and output the data in synchronization with the base clock, the n being an integer of one or more; and
a selection circuit that, on the basis of the selection signal, switches data to be inputted to each of the n stages of coupled holding circuits between the first synchronization signal and data outputted by a holding circuit, the holding circuit being one of the n stages of coupled holding circuits and preceding each holding circuit.

3. The clock synchronization circuit according to claim 1,
wherein the number of stages of the series-coupled holding circuits is determined in accordance with the division ratio of the system clock.

4. The clock synchronization circuit according to claim 1,
wherein, whether to output or stop outputting the second synchronization signal is determined on the basis of a control signal for determining whether to output the substrate synchronization signal.

5. The clock synchronization circuit according to claim 1,
wherein the predetermined time is a time obtained by multiplying a cycle of the base clock by the division ratio.

6. A semiconductor integrated circuit comprising:
the clock synchronization circuit according to claim 1;
a clock generation circuit that generates the base clock, the first synchronization signal, and the system clock; and
a bus master that operates on the basis of the base clock and the second synchronization signal.

7. The semiconductor integrated circuit according to claim 6,
wherein wiring for the base clock is branched into wiring coupled to the clock generation circuit and wiring coupled to a base clock input terminal of the bus master at a clock branch point, and
wherein the clock synchronization circuit is laid out within a range such that a delay variation between the base clock and the second synchronization signal is nearly eliminated by performing clock tree synthesis on the wiring between the clock branch point and the base clock input terminal of the bus master.

8. The semiconductor integrated circuit according to claim 6,
wherein the clock synchronization circuit comprises m stages of series-coupled clock synchronization circuits, the m being an integer of two or more.

9. The semiconductor integrated circuit according to claim 6, further comprising:
a bus transaction monitor that detects whether a bus is occupied by transfer data,
wherein, if the bus is not occupied by transfer data, the bus transaction monitor causes the clock synchronization circuit to stop outputting the second synchronization signal.

10. The semiconductor integrated circuit according to claim 9, further comprising:
a clock frequency change sequencer that, when receiving a request for changing the frequency of the system clock, requests the clock generation circuit to change the division ratio of the system clock,
wherein, when the bus transaction monitor detects that the bus is not occupied by transfer data, the clock generation circuit changes the division ratio of the system clock.
